(19) United States
(12) Patent Application Publication
(10) Pub. No.: US 2025/0234759 A1
(43) Pub. Date: Jul. 17, 2025

(54) OLED DISPLAY PANEL

(71) Applicant: Shenzhen China Star Optoelectronics Semiconductor Display Technology Co., Ltd., Shenzhen (CN)

(72) Inventor: Jing NI, Shenzhen (CN)

(73) Assignee: Shenzhen China Star Optoelectronics Semiconductor Display Technology Co., Ltd., Shenzhen (CN)

(21) Appl. No.: 18/931,043

(22) Filed: Oct. 30, 2024

(30) Foreign Application Priority Data
Jan. 12, 2024 (CN) 202410058028.4

(51) Int. Cl. H10K 59/80; H10K 59/40

(52) U.S. Cl. CPC H10K 59/879; H10K 59/40; H10K 59/873

(57) ABSTRACT

An OLED display panel includes: a base substrate; a light-emitting device layer situated on one side of the base substrate, which includes multiple light-emitting units; an encapsulation layer positioned on one side of the light-emitting device layer that faces away from the base substrate; an insulation layer positioned on one side of the encapsulation layer that faces away from the base substrate, which includes multiple protruding structures corresponding to the light-emitting units; a functional layer positioned on one side of the insulation layer that faces away from the base substrate; and a planarization layer positioned on one side of the functional layer that faces away from the base substrate. A refractive index of the functional layer is not less than a refractive index of the planarization layer. This configuration not only enhances the light output efficiency of the OLED device but also improves its reliability and mechanical resistance.

### FIELD OF DISCLOSURE

The present application relates to a field of display technology, and more particularly to an organic light-emitting diode (OLED) display panel.

### DESCRIPTION OF RELATED ART

Organic light-emitting diode (OLED) devices are lightweight, offer wide viewing angles, and have high luminous efficiency compared to conventional liquid crystal displays (LCDs).

A typical OLED display panel is composed of several layers, from bottom to top: a substrate, a thin-film transistor (TFT), an OLED device, an encapsulation layer, and a touch film layer. The substrate consists of flexible materials like polyimide (PI), known for their good flexibility and transparency. The TFT modulates the light emission of the OLED through signal control. To protect the OLED device from moisture and oxygen, it is typically encased in an inorganic-organic hybrid encapsulation layer that offers protection against water and oxygen. A touch film layer is applied over the encapsulation layer to provide touch functionality. However, to reduce the reflection of external light, a polarizer is often added above the touch layer. Although this reduces external light reflection, it also significantly decreases the light output efficiency of the OLED device.

Micro-lens Pattern (MLP) technology is a method employed to enhance the light output efficiency of OLED devices. This technology optimizes light transmission and focusing through the use of organic materials with varying refractive indices and strategically designed morphologies. Typically, the micro-lens structure is constructed using two layers of organic materials. However, traditional manufacturing techniques, such as coating and photolithography (photo), often lead to excessively thick layers of organic material and only limited improvements in refractive index.

### SUMMARY OF INVENTION

An objective of the present application is to provide an organic light-emitting diode (OLED) display panel to address the technical problems of low light output efficiency, severe light loss, and low refractive index in OLED devices.

To achieve the above objective, the present application provides an OLED display panel, including:
a base substrate;
a light-emitting device layer disposed on one side of the base substrate, the light-emitting device layer including a plurality of light-emitting units;
an encapsulation layer disposed on one side of the light-emitting device layer away from the base substrate;
an insulation layer disposed on one side of the encapsulation layer away from the base substrate, the insulation layer including a plurality of protruding structures, the protruding structures being disposed corresponding to the light-emitting units;
a functional layer disposed on one side of the insulation layer away from the base substrate; and
a planarization layer disposed on one side of the functional layer away from the base substrate;
wherein a refractive index of the functional layer is not less than a refractive index of the planarization layer.

Further, an elastic modulus of the functional layer is not less than an elastic modulus of the encapsulation layer.

Further, the elastic modulus of the functional layer is 90-100 GPa; the elastic modulus of the encapsulation layer is 70-100 GPa.

Further, the refractive index k of the functional layer satisfies: 1.7≤k≤2.0.

Further, the surface of the encapsulation layer close to the insulation layer is provided with grooves, the grooves being disposed on the outer periphery of the protruding structures; the functional layer covers the top surface and side surfaces of the protruding structures and the bottom surface of the grooves.

Further, each of the grooves surrounds the outer periphery of one of the protruding structures.

Further, the roughness of the surface of the functional layer away from the base substrate is less than the roughness of the bottom surface of the grooves. Further, the depth h of the grooves satisfies: h<150 nm.

Further, the insulation layer includes:
a first sub-insulation layer disposed on the side of the encapsulation layer away from the base substrate; and
a second sub-insulation layer disposed on the side of the first sub-insulation layer away from the base substrate, wherein the elongation at break of the first sub-insulation layer is less than the elongation at break of the functional layer, and the elongation at break of the second sub-insulation layer is less than the elongation at break of the functional layer.

Further, the OLED display panel further includes:
a touch layer, the touch layer including the first sub-insulation layer, a touch metal layer, and the second sub-insulation layer;
wherein the touch metal layer is located between the plurality of protruding structures; the material of the protruding structures is the same as the material of at least one of the first sub-insulation layer and the second sub-insulation layer.

Further, the touch layer includes a bridge region and a non-bridge region; the touch metal layer includes a first touch metal sublayer and a second touch metal sublayer;
the touch layer located in the bridge region includes the first sub-insulation layer, the first touch metal sublayer, the second sub-insulation layer, and the second touch metal sublayer sequentially disposed on the encapsulation layer; the second touch metal sublayer is electrically connected to the first touch metal sublayer through a via passing through the second sub-insulation layer, wherein the orthographic projection of the grooves on the base substrate is located between the orthographic projection of the bridge region on the base substrate and the orthographic projection of the protruding structures on the base substrate;
the touch layer located in the non-bridge region includes the first sub-insulation layer, the second sub-insulation layer, and the second touch metal sublayer sequentially disposed on the encapsulation layer, wherein the orthographic projection of the grooves on the base substrate is located between the orthographic projection of the non-bridge region on the base substrate and the orthographic projection of the protruding structures on the base substrate;
the functional layer covers one side of the second touch metal sublayer away from the base substrate.

Further, the protruding structures include:
a first sub-protruding structure located in the first sub-insulation layer;
a second sub-protruding structure located in the second sub-insulation layer.

Further, the material of the first sub-insulation layer is the same as the material of the second sub-insulation layer.

The technical effect of the present application is to provide an OLED display panel, by disposing an insulation layer, a functional layer, and a planarization layer on the encapsulation layer, wherein the insulation layer is provided with a plurality of protruding structures, and the refractive index of the functional layer is not less than the refractive index of the planarization layer, while improving the light output efficiency of the OLED device, the overall bending center plane of the OLED display panel can be closer to the encapsulation layer and the insulation layer, thereby reducing the stress and having a high resistance to fracturing (evidenced by a high elongation at break), reducing the risk of breakage. Furthermore, the functional layer is made of more corrosion-resistant and stable materials, which can provide better reliability for the OLED display panel, thereby extending the product's service life.

In summary, the OLED display panel provided by the present application can improve the light output efficiency from the OLED display panel's forward viewing angle, and also improve the reliability and mechanical resistance, which is expected to make flexible display technology more superior and play a more important role in future development.

### BRIEF DESCRIPTION OF DRAWINGS

The technical solutions and other beneficial effects of the present application become apparent from the following detailed description of specific embodiments of the present application in conjunction with the accompanying drawings.

FIG. 1 is a schematic partial cross-sectional view of a display panel according to one embodiment of the present application.

FIG. 2 is a schematic partial cross-sectional view of the display panel according to another embodiment of the present application.

FIG. 3 is a schematic partial cross-sectional view of the display panel according to yet another embodiment of the present application.

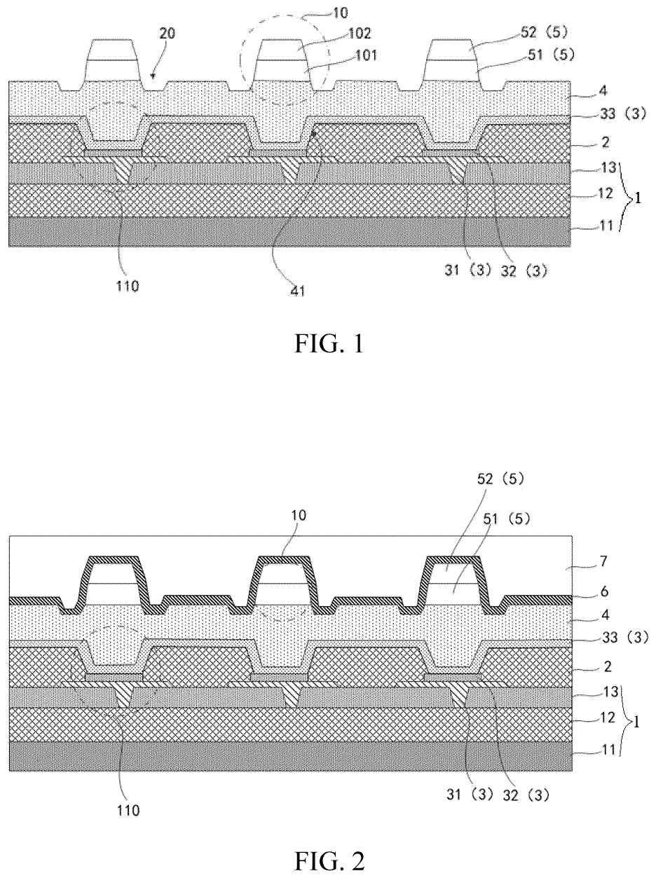

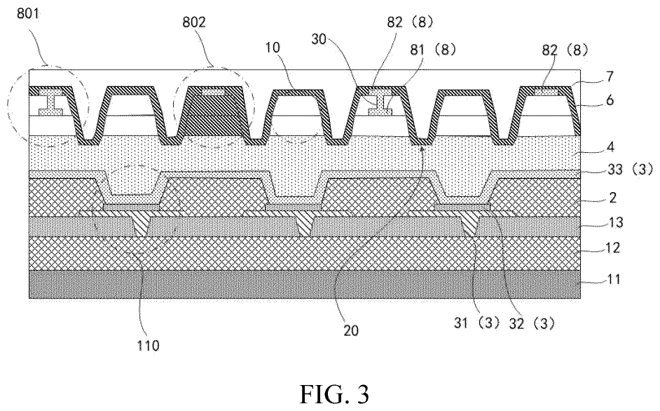

### REFERENCE NUMERALS IN THE DRAWINGS

1. array substrate; 11. substrate; 12. array layer; 13. passivation layer; 2. pixel definition layer; 3. light-emitting device layer; 31. anode; 32. light-emitting material layer; 33. cathode; 4. encapsulation layer; 110. light-emitting unit; 10. protruding structure; 20. groove; 30. via; 101. first sub-protruding structure; 102. second sub-protruding structure; 5. insulation layer; 51. first sub-insulation layer; 52. second sub-insulation layer; 6. functional layer; 7. planarization layer; 8. touch metal layer; 81. first touch metal sublayer; 82. second touch metal sublayer; 801. bridge region; 802. non-bridge region.

### DETAILED DESCRIPTION OF EMBODIMENTS

In the following, the technical solutions in the embodiments of the present application are clearly and completely described with reference to the accompanying drawings in the embodiments of the present application. Obviously, the described embodiments are only a part of the embodiments of the present application, not all embodiments. Based on the embodiments in the present application, all other embodiments obtained by those skilled in the art without creative effort are within the scope of protection of the present application.

In the description of the present application, it should be understood that the terms “first” and “second” are used for descriptive purposes only and should not be construed as indicating or implying relative importance or implicitly indicating the number of technical features indicated. Thus, features defined by “first” and “second” may explicitly or implicitly include one or more of the features. In the description of the present application, the meaning of “plurality” is two or more unless otherwise specifically defined.

In the description of the present application, it should be understood that unless otherwise expressly provided and limited, the terms “mounted,” “coupled,” and “connected” should be broadly construed, for example, they can be fixed connections, detachable connections, or integrally connected; they can be mechanical connections, electrical connections, or capable of communicating with each other; they can be directly connected or indirectly connected through an intermediate medium, and they can be internal connections between two components or interaction relationships between two components. For those skilled in the art, the specific meaning of the above terms in this application can be understood based on specific circumstances.

Some embodiments of the present application provide an OLED display panel, which includes an array substrate 1, a pixel definition layer 2, a light-emitting device layer 3, an encapsulation layer 4, an insulation layer 5, and a functional layer 6.

Specifically, the array substrate 1 includes, from bottom to top, a base substrate 11, an array layer 12, and a passivation layer 13. The base substrate 11 can be a flexible substrate 11, and the material of the base substrate 11 includes but is not limited to polyimide. The array layer 12 includes a plurality of driving circuit units, each driving circuit unit includes at least one thin-film transistor. The material of the passivation layer 13 includes at least one of SiNx, SiONx, and SiO₂.

The pixel definition layer 2 is disposed on the passivation layer 13. The pixel definition layer 2 is provided with a plurality of pixel openings 41 for exposing anodes 31 on the array substrate 1.

The light-emitting device layer 3 is disposed on one side of the base substrate 11. The light-emitting device layer 3 includes a plurality of light-emitting units 110 spaced apart from each other, and each light-emitting unit 110 is connected to one driving circuit unit. Specifically, the light-emitting device layer 3 includes an anode 31, a light-emitting material layer 32, and a cathode 33. The light-emitting material layer 32 is disposed on the anode 31 and is located in the pixel opening 41. The light-emitting material layer 32 includes a light-emitting functional layer and a common functional layer, and the common functional layer includes but is not limited to a hole transport layer and an electron transport layer. The cathode 33 is disposed on the light-emitting material layer 32 and extends to an upper surface of the pixel definition layer 2. In a specific embodiment, multiple light-emitting units 110 can share one single cathode 33.

The encapsulation layer 4 is disposed on one side of the light-emitting device layer 3 away from the base substrate 11. Specifically, the encapsulation layer 4 is disposed on the cathode 33 to encapsulate the light-emitting device layer 3, thereby blocking the intrusion of water and oxygen to enhance the yield of the OLED display panel. The encapsulation layer 4 can be formed by stacking multiple organic layers and inorganic layers.

The insulation layer 5 is disposed on one side of the encapsulation layer 4 away from the base substrate 11. Specifically, the insulation layer 5 is disposed on the encapsulation layer 4. The insulation layer 5 includes a plurality of protruding structures 10, and the protruding structures 10 are disposed corresponding to the light-emitting units 110. In a specific embodiment, an orthographic projection of the protruding structures 10 on the base substrate 11 at least partially overlaps with an orthographic projection of the light-emitting units 110 on the base substrate 11. In this way, by converging light, the light output efficiency of the light-emitting device can be improved, and the power consumption of the light-emitting device can be reduced.

In a specific embodiment, the insulation layer 5 includes a first sub-insulation layer 51 and a second sub-insulation layer 52. The first sub-insulation layer 51 and the second sub-insulation layer 52 are sequentially disposed on the encapsulation layer 4. The materials used for the first sub-insulation layer 51 and the second sub-insulation layer 52 can be the same or different. In one embodiment, the material of the first sub-insulation layer 51 is the same as the material of the second sub-insulation layer 52.

In a specific embodiment, the protruding structure 10 includes a first sub-protruding structure 101 and a second sub-protruding structure 102. The first sub-protruding structure 101 is located in the first sub-insulation layer 51. The second sub-protruding structure 102 is located in the second sub-insulation layer 52. The material of the protruding structure 10 is the same as the material of at least one of the first sub-insulation layer 51 and the second sub-insulation layer 52. Specifically, the protruding structure 10 can be formed by the first sub-insulation layer 51, or by the second sub-insulation layer 52, or by the stacking of the first sub-insulation layer 51 and the second sub-insulation layer 52.

In one embodiment, the material of the first sub-protruding structure 101 is the same as the material of the first sub-insulation layer 51. The material of the second sub-protruding structure 102 is the same as the material of the second sub-insulation layer 52. The materials of the first sub-insulation layer 51 and the second sub-insulation layer 52 both include at least one of SiNx, SiONx, and SiO₂.

The functional layer 6 is disposed on one side of the insulation layer 5 away from the base substrate 11. Specifically, the functional layer 6 is disposed on the insulation layer 5. The functional layer 6 can be prepared by deposition methods such as chemical vapor deposition (CVD) and atomic layer deposition (ALD). The material of the functional layer 6 is made of more corrosion-resistant and stable materials such as at least one of SiNx, SiONx, and SiO₂. The functional layer 6 can provide better reliability for the OLED display panel, thereby extending the product's service life.

In a specific embodiment, a surface of the encapsulation layer 4 close to the insulation layer 5 is provided with grooves 20. The grooves 20 are arranged around the outer periphery of the protruding structures 10. That is to say, the groove 20 is positioned on one or more sides of the protruding structure 10, enhancing the forward viewing angle's light output efficiency by converging light, which also reduces the product's power consumption. A higher light output efficiency allows achieving the same brightness level with lower power. In one embodiment, each of the grooves 20 encircles one of the protruding structures 10. That is to say, that is, the protruding structure 10 is surrounded by the groove 20, further enhancing the OLED device's light output efficiency, minimizing light loss, and thereby improving display brightness and clarity.

It should be noted that the protruding structure 10 can also be composed of a part of the encapsulation layer 4 and one or two insulation layers 5, as long as the light output efficiency of the OLED device can be improved and the light loss can be reduced; there is no specific limitation herein.

In a specific embodiment, the sidewalls of groove 20 are formed by the side surfaces of the encapsulation layer 4, the first sub-protruding structure 101, and the second sub-protruding structure 102. The side surface of the encapsulation layer 4 connects to the side surface of the first sub-protruding structure 101 and is on the same continuous plane, and the side surface of the first sub-protruding structure 101 is connected to the side surface of the second sub-protruding structure 102 and is located on the same continuous plane. Additionally, the grooves 20 and the protruding structures 10 are arranged in a spaced apart manner. In some embodiments, the groove 20 can enlarge the interface area between denser and less dense optical media, allowing a broader range of side-emitted light to converge towards the forward viewing direction, which aids in further enhancing the forward viewing angle's light output efficiency of the display panel.

In a specific embodiment, the depth h of the groove 20 satisfies: h<150 nm, increasing the film thickness of the Micro-lens Pattern (MLP) structure, and further improving the light output efficiency of the forward viewing angle of the OLED display panel.

The functional layer 6 covers top surfaces and side surfaces of the protruding structures 10 and bottom surfaces of the grooves 20, so as to improve the mechanical resistance of the OLED display panel, avoid cracks in the OLED display panel during bending, and thereby improve the yield of the OLED display panel. Specifically, since the sidewalls of the grooves 20 are also the side surfaces of the protruding structures 10, in other embodiments, the functional layer 6 covers the top surfaces of the protruding structures 10, and the side surfaces and the bottom surfaces of the grooves 20, which can also achieve the effect of improving the light output efficiency of the OLED display panel, and also improves the reliability and mechanical resistance.

In the embodiments of this application, the functional layer 6 is positioned on the insulation layer 5. When the OLED display panel bends, the central plane of bending moves closer to the encapsulation layer 4 and the insulation layer 5. This proximity reduces the stress experienced by the display panel, thereby increasing its resistance to fracturing (evidenced by a high elongation at break) and reducing the risk of breakage.

In a specific embodiment, the roughness of a surface of the functional layer 6 away from the base substrate 11 is less than the roughness of the bottom surfaces of the grooves 20. It should be noted that since the protruding structures 10 are formed by etching the insulation layer 5 and the encapsulation layer 4, the protruding structures 10 generate defects such as burrs or notches during etching, reducing the stress concentration of the panel, thereby leading to defects that the panel is prone to fracture during bending. Therefore, in some embodiments of the present application, the roughness of the upper surface of the functional layer 6 is less than the roughness of the bottom surfaces of the grooves 20, which can reduce the burrs or notches caused by the etching process, so that the stress on the panel is reduced, and the risk of breakage is reduced.

Further, the roughness of the surface of the functional layer 6 away from the base substrate 11 is less than the roughness of the surfaces of the protruding structures 10. Specifically, the roughness of the upper surface of the functional layer 6 is less than the roughness of the side surface of the first sub-protruding structure 101, and also less than the roughness of the upper surface and side surface of the second sub-protruding structure 102. The roughness of the first sub-protruding structure 101 and the roughness of the second sub-protruding structure 102 can be the same or different, depending on the materials used for the first sub-protruding structure 101 and the second sub-protruding structure 102; however, the present application is not limited in this regard.

In a specific embodiment, a refractive index k of the functional layer 6 satisfies: 1.7≤k≤2.0, so as to reduce the stress on the insulation layer 5 during the compression of the OLED display panel screen, and effectively reduce the tensile strain of the insulation layer 5.

In a specific embodiment, the elastic modulus of the functional layer 6 is not less than the elastic modulus of the encapsulation layer 4. This arrangement positions the bending center plane of the OLED display panel closer to the encapsulation layer 4 and the insulation layer 5 above the encapsulation layer 4. Consequently, this reduces the stress experienced by the OLED display panel, enhances its resistance to fracturing (evidenced by a high elongation at break), and lowers the risk of breakage.

In a specific embodiment, the elastic modulus of the functional layer 6 ranges from 90 to 100 GPa, and the elastic modulus of the encapsulation layer 4 ranges from 70 to 100 GPa. This configuration enables the OLED display panel to achieve high resistance to fracturing (evidenced by a high elongation at break), thereby reducing the risk of breakage.

In a specific embodiment, the elongation at break of the first sub-insulation layer 51 is less than the elongation at break of the functional layer 6, and the elongation at break of the second sub-insulation layer 52 is also less than the elongation at break of the functional layer 6. The material used for the functional layer 6 is an inorganic material, for example, including at least one of SiNx, SiONx, and SiO₂. In this way, when the OLED panel bends, the bending center of the panel is closer to the encapsulation layer 4 and the insulation layer 5 located above the encapsulation layer 4. This allows the functional layer 6 to reduce the stress experienced by the overall inorganic layers (i.e., the insulation layer 5), enhancing its anti-fracture elongation and reducing the risk of breakage.

In some embodiments of the present application, the OLED display panel further includes a planarization layer 7, which is disposed on one side of the functional layer 6 away from the base substrate 11. A refractive index of the functional layer 6 is not less than a refractive index of the planarization layer 7, thereby further improving the light output efficiency from the forward viewing angle of the display panel.

In some embodiments of the present application, the OLED display panel provides touch function, which includes the technical solutions of the OLED display panel mentioned above, and further includes a touch layer, and the touch layer includes the first sub-insulation layer 51, a touch metal layer 8, and the second sub-insulation layer 52.

The touch metal layer 8 is located between multiple protruding structures 10. Specifically, in the embodiments of the present application, the first sub-insulation layer 51 and the second sub-insulation layer 52 in the touch layer are repurposed as micro-lens structures. This approach eliminates the need for an additional film layer for forming the micro-lens structure, thus enhancing the OLED display panel's light output efficiency while simultaneously reducing its thickness.

The touch layer includes a bridge region 801 and a non-bridge region 802. The touch metal layer 8 includes a first touch metal sublayer 81 and a second touch metal sublayer 82.

The touch layer located in the bridge region 801 includes the first sub-insulation layer 51, the first touch metal sublayer 81, the second sub-insulation layer 52, and the second touch metal sublayer 82 sequentially disposed on the encapsulation layer 4. The second touch metal sublayer 82 is electrically connected to the first touch metal sublayer 81 through a via 30 passing through the second sub-insulation layer 52. Wherein, the vias 30 can be formed in the same process as the grooves 20, which can save process steps and is beneficial to improve production efficiency and reduce costs.

The touch layer located in the non-bridge region 802 includes the first sub-insulation layer 51, the second sub-insulation layer 52, and the second touch metal sublayer 82 sequentially disposed on the encapsulation layer 4. It should be noted that in other embodiments, the touch layer located in the non-bridge region 802 includes the first sub-insulation layer 51, the first touch metal sublayer 81, and the second sub-insulation layer 52 sequentially disposed on the encapsulation layer 4, but the present application is not limited in this regard.

In a specific embodiment, an orthographic projection of the grooves 20 projected on the base substrate 11 is located between an orthographic projection of the bridge region 801 on the base substrate 11 and an orthographic projection of the protruding structures 10 on the base substrate 11. The orthographic projection of the grooves 20 projected on the base substrate 11 is also located between an orthographic projection of the non-bridge region 802 on the base substrate 11 and the orthographic projection of the protruding structures 10 on the base substrate 11. In this way, the groove 20 can be disposed around the protruding structure 10, which is beneficial to simplify the process while improving the forward light output efficiency from the display panel.

In a specific embodiment, the functional layer 6 covers one side of the second touch metal sublayer 82 away from the base substrate 11, extending to the top surfaces and side surfaces of the protruding structures 10, as well as the bottom surfaces of the grooves 20. When the OLED display panel bends, the overall bending center plane of the display panel shifts closer to the encapsulation layer 4 and the touch layer, so that the stress is reduced, thereby enhancing the display panel's fracture resistance (evidenced by a high elongation at break), reducing the risk of breakage.

Therefore, the OLED display panel provided in the embodiments of the present application improves the reliability and mechanical resistance while improving the light output efficiency of the OLED device.

The above has described in detail the OLED display panel provided in the embodiments of the present application. In this disclosure, specific examples are used to illustrate the principles and implementation methods of the present application. The description of the above embodiments is only for helping to understand the technical solutions and core ideas of the present application; those skilled in the art should understand that they can still modify the technical solutions described in the foregoing embodiments, or make equivalent replacements for some of the technical features therein; and these modifications or replacements do not make the essence of the corresponding technical solutions depart from the scope of the technical solutions of the embodiments of the present application.

What is claimed is:

1. An organic light-emitting diode (OLED) display panel, comprising:
a base substrate;
a light-emitting device layer, disposed on one side of the base substrate, wherein the light-emitting device layer comprises a plurality of light-emitting units;
an encapsulation layer disposed on the side of the light-emitting device layer away from the base substrate;
an insulation layer disposed on one side of the encapsulation layer away from the base substrate, wherein the insulation layer comprises a plurality of protruding structures, and the protruding structures are disposed corresponding to the light-emitting units;
a functional layer disposed on one side of the insulation layer away from the base substrate; and
a planarization layer disposed on one side of the functional layer away from the base substrate;
wherein a refractive index of the functional layer is at least equal to a refractive index of the planarization layer.

2. The OLED display panel according to claim 1, wherein an elastic modulus of the functional layer is equal to or greater than an elastic modulus of the encapsulation layer.

3. The OLED display panel according to claim 1, wherein the elastic modulus of the functional layer ranges from 90 to 100 GPa, and the elastic modulus of the encapsulation layer ranges from 70 to 100 GPa.

4. The OLED display panel according to claim 1, wherein the refractive index of the functional layer satisfies: 1.7≤k≤2.0.

5. The OLED display panel according to claim 1, wherein a surface of the encapsulation layer close to the insulation layer is provided with a plurality of grooves, each of the grooves being disposed around an outer periphery of one of the protruding structures; the functional layer covers top surfaces and side surfaces of the protruding structures, and bottom surfaces of the grooves.

6. The OLED display panel according to claim 5, wherein each of the grooves encloses the outer periphery of one of the protruding structures.

7. The OLED display panel according to claim 5, wherein roughness of a surface of the functional layer away from the base substrate is less than roughness of the bottom surfaces of the grooves.

8. The OLED display panel according to claim 5, wherein a depth h of each of the grooves satisfies: h<150 nm.

9. The OLED display panel according to claim 5, wherein the insulation layer comprises:
a first sub-insulation layer disposed on one side of the encapsulation layer away from the base substrate; and
a second sub-insulation layer disposed on one side of the first sub-insulation layer away from the base substrate, wherein an elongation at break of the first sub-insulation layer is less than an elongation at break of the functional layer, and an elongation at break of the second sub-insulation layer is less than the elongation at break of the functional layer.

10. The OLED display panel according to claim 9, further comprising:
a touch layer, comprising the first sub-insulation layer, a touch metal layer, and the second sub-insulation layer;
wherein the touch metal layer is located between the multiple protruding structures; a material of the protruding structures is same as a material of at least one of the first sub-insulation layer and the second sub-insulation layer.

11. The OLED display panel according to claim 10, wherein the touch layer includes a bridge region and a non-bridge region, and the touch metal layer includes a first touch metal sublayer and a second touch metal sublayer;
the touch layer located in the bridge region includes the first sub-insulation layer, the first touch metal sublayer, the second sub-insulation layer, and the second touch metal sublayer sequentially disposed on the encapsulation layer; the second touch metal sublayer is electrically connected to the first touch metal sublayer through a via passing through the second sub-insulation layer, wherein an orthographic projection of the grooves projected on the base substrate is located between an orthographic projection of the bridge region projected on the base substrate and an orthographic projection of the protruding structures projected on the base substrate;
the touch layer located in the non-bridge region includes the first sub-insulation layer, the second sub-insulation layer, and the second touch metal sublayer sequentially disposed on the encapsulation layer, wherein the orthographic projection of the grooves projected on the base substrate is located between an orthographic projection of the non-bridge region projected on the base substrate and the orthographic projection of the protruding structures projected on the base substrate;
the functional layer covers one side of the second touch metal sublayer away from the base substrate.

12. The OLED display panel according to claim 9, wherein the protruding structure comprises:
a first sub-protruding structure disposed in the first sub-insulation layer; and
a second sub-protruding structure disposed in the second sub-insulation layer.

13. The OLED display panel according to claim 9, wherein a material of the first sub-insulation layer is the same as a material of the second sub-insulation layer.
